(19) United States
(12) Patent Application Publication
(10) Pub. No.: US 2023/0069969 A1
(43) Pub. Date: Mar. 9, 2023

(54) PACKAGE FOR SEVERAL INTEGRATED CIRCUITS

(71) Applicants: STMicroelectronics (Grenoble 2) SAS, Grenoble (FR); STMicroelectronics (Alps) SAS, Grenoble (FR)

(72) Inventors: Younes BOUTALEB, Grenoble (FR); Laurent SCHWARTZ, La Buisse (FR)

(73) Assignees: STMicroelectronics (Grenoble 2) SAS, Grenoble (FR); STMicroelectronics (Alps) SAS, Grenoble (FR)

(21) Appl. No.: 17/903,280

(22) Filed: Sep. 6, 2022

(30) Foreign Application Priority Data
Sep. 8, 2021 (FR) 2109386

(51) Int. Cl. H01L 23/367; H01L 23/00; H01L 25/065; H01L 23/373

(52) U.S. Cl. CPC H01L 23/3672; H01L 24/48; H01L 24/32; H01L 24/16; H01L 24/73; H01L 25/0655; H01L 23/3737; H01L 2924/182; H01L 2224/48225; H01L 2224/48245; H01L 2224/32225; H01L 2224/32245; H01L 2224/16225; H01L 2224/73204; H01L 2224/73253; H01L 2224/73265; H01L 2224/48105

(57) ABSTRACT

A package for integrated circuits includes a base substrate having a mounting face. A first electronic chip has a top face electrically connected to the mounting face and a bottom face mounted to the mounting face by an adhesive layer. A second electronic chip has a bottom face covered with a thermal interface layer and a top face electrically connected to the mounting face. A heat sink includes a first part embedded in the adhesive layer, a second part having a bottom face in contact with the layer of thermal interface material and a top face, and a connection part between the first part and the second part. A coating encapsulates the first and second electronic chips and the heat sink. The top face of the second part of the heat sink exposed from the encapsulating coating.

### PRIORITY CLAIM

This application claims the priority benefit of French Application for Patent No. 2109386, filed on Sep. 8, 2021, the content of which is hereby incorporated by reference in its entirety to the maximum extent allowable by law.

### TECHNICAL FIELD

Implementations and embodiments relate to the field of microelectronics and, in particular, to the field of integrated circuit packaging and, more particularly, to the heat dissipation of packages containing several integrated circuits of different types.

### BACKGROUND

Conventionally, a type of integrated circuit package includes an electronic integrated circuit chip disposed on a face of a base substrate and protected by a coating, typically a resin, molded to encapsulate around the chip and rigidly connected to the base substrate. The other face of the base substrate can include electrical connections, for example balls, intended to be mounted on a printed circuit board (PCB).

This coating (encapsulating) resin makes it possible not only to protect the chip but also to contribute to the robustness of the package.

In some applications, it may be provided to dispose several electronic chips on the same base substrate and all coated with the same coating resin.

Furthermore, in some cases, these different chips can be electrically connected to the base substrate using different methods.

A first method can use wire bonding technology. More specifically, such an electronic chip has a top face electrically connected to the base substrate by electrical connection wires and a bottom face mounted on the base substrate by a layer of adhesive.

A second method can use so-called “Flip Chip” technology. More specifically, such an electronic chip has a bottom face and a top face electrically connected to the base substrate by electrically conductive connection means, for example balls, embedded in a layer of an underfill material.

In operation, these different chips emit heat. It is then necessary to evacuate this heat as much as possible in such a way that the temperature of the integrated circuits does not attain a value resulting in the degradation thereof.

In this regard, it is possible, in terms of flip chip, to dispose a layer of thermal interface material (TIM), well-known to a person skilled in the art, on the bottom face of the chip and cover this thermal interface layer by a heat sink, for example a copper plate, the coating resin leaving the top face of the heat sink exposed.

That being said, the proximity of the different chips induces mutual heating of the chips and it then becomes necessary to move the chips away from one another so as to limit the heating of one chip by the emission of heat from a neighboring chip.

However, this leads to an increase in the size of the base substrate and hence to an increase in the size of the package.

Therefore, there is a need to enhance the heat dissipation of packages containing several chips electrically connected in different ways, while not increasing the size of these packages excessively, or at all.

### SUMMARY

In this regard, it is proposed according to an embodiment to embody a heat sink having a particular shape, for example in the shape of an inverted half-hat or inverted hat, such that it is, on one hand, in contact with the thermal interface layer of the flip chip and, on the other, embedded in the thermally conductive adhesive layer of the other chip.

According to an aspect, a package for integrated circuits comprises: a base substrate having a mounting face; at least a first electronic chip having a top face electrically connected to said mounting face by electrical connection wires and a bottom face mounted on the mounting face by an at least thermally conductive adhesive layer; at least a second electronic chip having a bottom face covered with a layer of a thermal interface material and a top face electrically connected to the mounting face by electrically conductive connections embedded in a layer of an underfill material; a heat sink having a first part embedded in the at least thermally conductive adhesive layer, a second part having a bottom face in contact with the layer of thermal interface material and a top face, and a connection part between the first part and the second part; and a coating that encapsulates said at least two chips and the heat sink leaving the top face of the second part of the heat sink exposed.

The heat sink has thus, for example, an inverted half-hat shape.

Heat dissipation is performed both outwards by way of the second part of the heat sink, and by the base substrate by way of the thermally conductive adhesive layer.

The heat dissipation of the package is therefore enhanced without having to increase the space between the chips.

Furthermore, the particular shape of the heat sink, for example made of copper, and in particular the addition of the first part and of the connection part, helps increase the rigidity of the electronic package.

According to an embodiment, the adhesive layer can also be electrically conductive and rest on a contact pad of the mounting face intended to be connected to a cold power supply point, for example the ground. And at least one electrical connection wire is advantageously connected between the top face of said at least one first electronic chip and the connection part of the heat sink.

The heat sink can act as a ground plane and the connection of the first chip to the ground is facilitated with the use of one or more shorter electrical connection wires.

According to an embodiment, the package can include several first chips and/or several second chips.

For example, the package can comprise at least another second chip electrically connected to the top face of the base substrate and covered with another layer of thermal interface material.

Said at least one first electronic chip can be framed by the second electronic chip and the other second electronic chip.

The heat sink can include another second part located above the other layer of thermal interface material and another connection part between the first part and the other second part.

The connection part and/or the other connection part of the heat sink can then include one or more slots enabling the passage of some at least of the electrical connection wires.

### BRIEF DESCRIPTION OF THE DRAWINGS

Further advantages and features of the invention will become apparent on studying the detailed description of embodiments and implementations, in no way restrictive, and of the appended drawings wherein:

FIG. 1 schematically illustrates a sectional view of a package for integrated circuits;

FIG. 2 schematically illustrates a sectional view of a package for integrated circuits; and

FIG. 3 specifically partially represents the heat sink in FIG. 2.

### DETAILED DESCRIPTION

FIG. 1 schematically illustrates a sectional view of a package BT for integrated circuits according to an embodiment of the invention. The package BT comprises a base substrate SS having a top mounting face FM. The package BT further comprises at least a first electronic integrated circuit chip P1 and at least a second electronic integrated circuit chip P2.

The first electronic chip P1 has a top face FS1 and a bottom face FI1. The top face FS1 of the chip P1 is electrically connected to the mounting face FM of the base substrate SS by connection wires WB1 soldered to connection pads of the chip P1 and the base substrate SS. The bottom face FI1 of the chip P1 is mounted on the mounting face FM by an adhesive layer 1 well-known to a person skilled in the art. The adhesive layer 1 is thermally conductive and therefore makes it possible to dissipate towards the base substrate, the heat emitted by the chip P1 when it is in operation.

The electronic chip P1 is therefore connected to the base substrate SS using wire bonding technology.

The second electronic chip P2 has a bottom face FI2 and a top face FS2. The bottom face FI2 of the chip P2 is covered by the bottom face 30 of a layer of a thermal interface material 3, well-known to a person skilled in the art. By way of non-restrictive example, it is for example possible to use the material from the company DOW known under the trade name DOWSIL DA-6534 which is a conductive adhesive having a high thermal conductivity, typically 6.8 watts per meter and per degree Kelvin.

The top face FS2 of the chip P2 is electrically connected to the mounting face FM by connections 2. The connections 2 can be connection balls, for example, and are generally embedded in a layer of an underfill material 20. The underfill layer, well-known to a person skilled in the art, can be formed by a resin, for example.

The electronic chip P2 is therefore connected to the base substrate SS using “Flip Chip” technology.

The package BT also comprises a heat sink 4 which is generally formed by a heat-conducting material such as copper, for example. The heat sink 4 has a first part 41 and a second part 42. The first part 41 of the heat sink 4 is embedded in the thermally conductive adhesive layer 1 and is located below the first electronic chip P1. The adhesive layer 1 is then separated into two adhesive sublayers by the first part 41. A first adhesive sublayer is located between the bottom face FI1 of the chip P1 and the first part 41 and a second sublayer is located between the first part 41 and the base substrate SS. Preferably, the thickness of the adhesive layer 1 is the same on either side of the first part 41 of the heat sink 4, and can be 30 μm for example.

The thermally conductive adhesive 1 therefore provides a heat transfer from the first chip P1 to the first part 41 of the heat sink 4, on one hand, and from the first part 41 of the heat sink 4 to the base substrate SS, on the other.

The second part 42 of the heat sink 4 has a bottom face 421 and a top face 420. The bottom face 421 is in contact with the top face 31 of the layer of thermal interface material 3 and is located above the second electronic chip P2.

The heat sink 4 further comprises a connection part 43 between the first part 41 and the second part 42. The connection part 43 is inclined in such a way as to connect the first part 41 with the second part 42 which are on two different planes. The heat sink 4 can therefore have here an inverted half-hat shape for example.

The package BT further comprises a coating 5. The coating 5 encapsulates the chips P1 and P2 as well as the heat sink 4 while leaving the top face 420 of the second part 42 of the heat sink 4 exposed. More particularly, the coating 5 can be formed by a similar resin to that used for the underfill layer for example. Such a material has advantageous mechanical properties enabling the package BT to withstand the mechanical stress liable to be applied thereon and protect the chips P1 and P2.

The thermal interface layer 3 provides a heat transfer from the second chip P2 to the second part 42 of the heat sink 4. The second part 42 of the heat sink 4 can then evacuate the heat transmitted by the layer of thermal interface material 3 outside the package BT without being impeded by the coating 5 since the top face 420 thereof is clear.

Thus, the heat dissipation of the first chip P1 is performed both outwards by way of the thermally conductive adhesive layer 1, the first part 41, the connection part 43 and the second part 42, and towards the base substrate SS by way of the thermally conductive adhesive layer 1 and the first part 41.

The heat dissipation of the second chip P2 is performed both outwards by way of the layer 3 and the second part 42, and towards the base substrate SS by way of the layer 3 and the second part 42, the connection part 43, the first part 41, and the thermally conductive adhesive layer 1.

The heat dissipation of the package BT is therefore enhanced without having to increase the space between the chips P1 and P2. Thus, while two neighboring chips in packages according to the prior art must be spaced apart so as to limit the heating of a chip by the emission of heat from the neighboring chip, the chips P1 and P2 can here be closer in the same package BT according to an embodiment while avoiding increased heating between the chips P1 and P2.

Although this is not mandatory, the adhesive layer 1 can be not only thermally conductive but also electrically conductive. It is possible, for example, to use the adhesive from the company Alpha Advanced Materials known under the trade name ATROX 800HT2V-P1 which has an electrical resistivity of 0.00001 ohm-cm.

Moreover, the mounting face FM of the base substrate has here a contact pad 10 intended to be connected to a cold power supply point, the ground for example. The adhesive layer 1, in particular the adhesive sublayer between the base substrate SS and the first part 41 of the heat sink, rests on this contact pad 10. The first part 41 is therefore embedded in an adhesive layer 1 and the heat sink 4 is then electrically connected to the cold power supply point and hence acts as a ground plane. It is thus possible to make use of the particular shape of the heat sink 4, particularly of the inclination of the connection part 43 to establish a connection between a contact pad of the top face FS1 of the chip P1 and the heat sink 4 using a shorter connection wire WB2, so as to connect this contact pad to the ground.

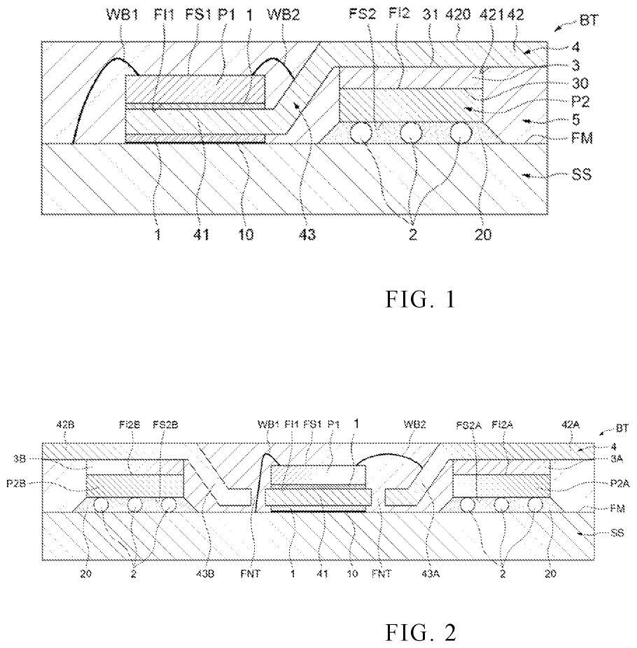

In the case of larger sized packages such as the package BT illustrated in FIG. 2, further electronic chips can be provided. The package BT then comprises for example at least another second chip P2B in addition to the first chip P1 and the second chip P2A corresponding respectively to the chips P1 and P2 in FIG. 1.

The chip P1 uses wire bonding technology and the chip P2A so-called “Flip-Clip” technology.

The other second chip P2B uses the same technology as the chip P2A, i.e., so-called “Flip-Chip” technology.

Similarly to the second chip P2A, the other second chip P2B is electrically connected to the mounting face FM of the base substrate SS and is covered with another layer of thermal interface material 3B, for example identical to the thermal interface material 3A. The first chip P1 is framed by the second electronic chip P2A and the other second electronic chip P2B.

The heat sink 4 further includes another second part 42B and another connection part 43B. The other second part 42B is located above the other layer of thermal interface material 3B and the other connection part 43B is located between the first part 41 and the other second part 42B. The heat sink 4 has thus an inverted half-hat shape.

Everything that has been described above for the second chip P2 in FIG. 1, particularly the advantages in terms of heat dissipation, applies to the second chip P2A and to the second chip P2B, the elements associated with the second chip P2A and with the second chip P2B, similar to those associated with the second chip P2 in FIG. 1, have references respectively assigned the letters A and B with respect to the references of these equivalent elements in FIG. 1.

Moreover, one of the connection parts, for example the connection part 43B of the heat sink 4 includes a slot FNT enabling the passage of the WB1 type connection wires. In this example, the connection wire WB2 is then connected to the other connection part 43A. However, the other connection part 43A can also include a slot FNT enabling the passage of another WB1 type connection wire not shown in FIG. 2.

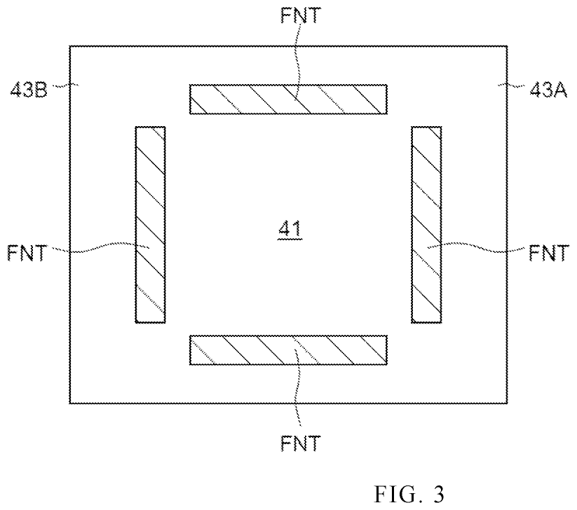

As illustrated more precisely in FIG. 3 which specifically partially represents the heat sink 4 in FIG. 2, the latter can include several separate slots FNT for the passage of other WB1 type connection wires. The slots FNT do not interrupt the thermal and optionally electrical continuity of the heat sink 4.

1. A package for integrated circuits, comprising:
a base substrate having a mounting face;
a first electronic chip having a top face electrically connected to said mounting face by electrical connection wires and a bottom face mounted to the mounting face through a thermally conductive adhesive layer;
a second electronic chip having a bottom face covered with a layer of a thermal interface material and a top face electrically connected to the mounting face by electrically conductive connections embedded in a layer of an underfill material;
a heat sink having a first part embedded in the thermally conductive adhesive layer, a second part having a bottom face in contact with the layer of thermal interface material and a top face, and a connection part between the first part and the second part; and
a coating that encapsulates said first and second electronic chips and the heat sink, wherein the top face of the second part of the heat sink is exposed from the coating.

2. The package according to claim 1, wherein the thermally conductive adhesive layer is also electrically conductive and rests on a contact pad of the mounting face intended to be connected to a cold power supply point, and wherein at least one electrical connection wire is connected between the top face of said first electronic chip and the connection part of the heat sink.

3. The package according to claim 1, further comprising another second electronic chip electronically connected to the mounting face of the base substrate and covered with another layer of thermal interface material, wherein said first electronic chip is framed on opposite sides by the second electronic chip and the another second electronic chip, and wherein the heat sink further includes another second part located above the another layer of thermal interface material and another connection part between the first part and the another second part, and wherein one or more of the connection part and the another connection part includes one or more slots enabling passage of electrical connection wires.

4. A package for integrated circuits, comprising:
a base substrate having a mounting face;
a heat sink having a first part, a second part and a connection part between the first part and the second part;
wherein the first part of the heat sink is mounted to the mounting face of the base substrate;
a first electronic chip having a top face electrically connected to said mounting face by an electrical connection wire and a bottom face mounted to the first part of the heat sink;
a second electronic chip having a top face electrically connected to the mounting face by electrically conductive connections embedded in a layer of an underfill material and a bottom face mounted to an underside of the second part of the heat sink by a layer of a thermal interface material; and
a coating that encapsulates said first and second electronic chips and the heat sink, wherein a top face of the second part of the heat sink is exposed from the coating.

5. The package according to claim 4, wherein said electrical connection wire passes through a slots in the heat sink.

6. The package according to claim 4, wherein said connection part is inclined and said first and second parts are on different planes.

7. The package according to claim 4, further comprises an adhesive material for mounting the first part of the heat sink to the mounting face of the base substrate.

8. The package according to claim 7, wherein said adhesive material further mounts the bottom face of the first electronic chip to the first part of the heat sink.

9. A package for integrated circuits, comprising:
a base substrate having a mounting face;
a first electronic chip mounted to the mounting face of the base substrate;
a heat sink having a first part, a second part and a connection part between the first part and the second part;
wherein the first part of the heat sink is mounted to the mounting face of the base substrate and the second part is mounted over the first electronic chip;
a second electronic chip mounted over the first part of the heat sink;
a coating that encapsulates said first and second electronic chips and the heat sink, wherein a top face of the second part of the heat sink is exposed from the coating.

10. The package according to claim 9, further comprising:
first electrical connections between the first electronic chip and the base substrate; and
second electrical connections between the second electronic chip and the base substrate.

11. The package according to claim 10, wherein said first electrical connections comprise electrical connection wires passing through one or more slots in the heat sink.

12. The package according to claim 11, wherein said one or more slots are located in the connection part of the heatsink.

13. The package according to claim 9, wherein said connection part is inclined and said first and second parts are on different planes.

14. The package according to claim 9, further comprising a thermally conductive adhesive embedding the first part of the heat sink attaching the first part to the mounting face of the base substrate and attaching the second electronic chip to the first part of the heat sink.

15. The package according to claim 9, further comprising a thermally conductive adhesive between the second part of the heat skink and the first electronic chip.
